(19) United States
(12) Patent Application Publication
(10) Pub. No.: US 2013/0037878 A1
(43) Pub. Date: Feb. 14, 2013

(54) VDMOS DEVICE AND METHOD FOR FABRICATING THE SAME

(71) Applicant: Le Wang, Wuxi City (CN)

(72) Inventor: Le Wang, Wuxi City (CN)

(73) Assignees: CSMC TECHNOLOGIES FAB2 CO., LTD., Wuxi City, Jiangsu (CN); CSMC TECHNOLOGIES FAB1 CO., LTD., Wuxi City, Jiangsu (CN)

(21) Appl. No.: 13/695,013

(22) PCT Filed: Jun. 23, 2011
(86) PCT No.: PCT/CN2011/076175

§ 371 Date: Oct. 26, 2012

(30) Foreign Application Priority Data
Jun. 25, 2010 (CN) 201010213340.4

(51) Int. Cl. H01L 29/78; H01L 21/20

(52) U.S. Cl. 257/329; 438/478; 257/E21.09; 257/E29.262

(57) ABSTRACT

A method for fabricating VDMOS devices includes providing a semiconductor substrate; forming a first N-type epitaxial layer on the semiconductor substrate; forming a hard mask layer with an opening on the first N-type epitaxial layer; etching the first N-type epitaxial layer along the opening until the semiconductor substrate is exposed, to form P-type barrier figures; forming a P-type barrier layer in the P-type barrier figures, the P-type barrier layer having a same thickness as that of the first N-type epitaxial layer; removing the hard mask layer; forming a second N-type epitaxial layer on the first N-type epitaxial layer and the P-type barrier layer; forming a gate on the second N-type epitaxial layer; forming a source in the second N-type epitaxial layer on both side of the gate; and forming a drain on the back of the semiconductor substrate relative to the gate and the source.

### CROSS-REFERENCE TO RELATED APPLICATION

The present application claims priority of the Chinese Application filed with the State Intellectual Property Office (SIPO) on Jun. 25, 2010, under application number 201010213340.4, and the application name “VDMOS Device and Method for Fabricating the Same”, the content of which is included in the present application through reference.

### TECHNICAL FIELD

The present disclosure relates to power devices, and in particular, relates to a method for fabricating VDMOS devices by selective epitaxy process and the structure of the VDMOS devices.

### RELATED ART

As a kind of power device, Vertical Double-Diffused Metal Oxide Semiconductor Field Effect Transistors (VDMOS) have advantages of high input impedance and low conduction voltage drop. Therefore, VDMOS devices are widely used.

A conventional method for fabricating VDMOS devices, such as disclosed in the Chinese patent application with the application number 200810057881.5, is described in detail referring to FIGS. 1 through 4. Referring to FIG. 1, firstly, an N-type semiconductor substrate 100 is provided, and an N-type epitaxial layer 101 is formed on the N-type semiconductor substrate 100. Sequentially, a gate oxide layer 111 is formed on the N-type epitaxial layer 101, and a poly gate layer 108 is formed on the gate oxide layer 111. Referring to FIG. 2, a P-well 107 is formed through a P-well implantation on the N-type epitaxial layer 101. The P-well 107 is located on both sides of the poly gate layer 108. Subsequently, a P-type barrier layer 104 is formed through ion implantation on the N-type epitaxial layer 101 below the P-well 107. Referring to FIG. 3, a heavy doped ion implantation is used to form an N-type heavy-doped area 106 in the P-well 107. Finally, referring to FIG. 4, a metallization process is carried out to form a gate metal layer 109 on the poly gate layer 108, a source metal layer 110 on the N-type heavy-doped area 106, and a drain metal layer 112 on the back of the semiconductor substrate 100. The “back” shall mean the side of the semiconductor substrate 100 opposite the side on which the devices are formed. The gate metal layer 109 and the poly gate layer 108 cooperatively make a gate G, the source metal layer 110 and the N-type heavy-doped area 106 cooperatively make a source S, and the drain metal layer 112 and the semiconductor substrate 100 cooperatively make a drain D.

According to the conventional technology, the doped impurity in the P-type barrier layer lacks uniformity, and therefore increases the conduction voltage drop and the channel resistor.

In order to fix the above problem, conventional technology uses multiple ion implantation and high temperature annealing steps on the N-type epitaxial layer 101 to form the P-type barrier layer on both sides of the N-type epitaxial layer 101. However, the multiple steps of the ion implantation and the high temperature annealing processes are too complex, the uniformity of the ion implantation is not easy to control, and may increase the manufacturing cost.

Therefore, it is desired to provide a method for fabricating VDMOS devices, which forms P-type barrier layers with good uniformity while simplifying the process, being easy to control, and having low manufacturing cost.

### SUMMARY

The present disclosure provides a method for fabricating VDMOS devices, which forms a P-type barrier layer with good uniformity, being simple in process and easy to control, and having a low cost for fabrication.

For the above-described requirement, in at least one embodiment, the present disclosure provides a method for fabricating a VDMOS device, the method including:

providing a semiconductor substrate, wherein a first N-type epitaxial layer is formed on the semiconductor substrate;

forming a hard mask layer with an opening on the first N-type epitaxial layer;

etching the first N-type epitaxial layer along the opening until the semiconductor substrate is exposed, to form P-type barrier figures;

forming a P-type barrier layer in the P-type barrier figures, wherein the P-type barrier layer has a same thickness as that of the first N-type epitaxial layer;

removing the hard mask layer;

forming a second N-type epitaxial layer on the first N-type epitaxial layer and the P-type barrier layer;

forming a gate on the second N-type epitaxial layer;

forming a source in the second N-type epitaxial layer on both sides of the gate; and

forming a drain on the back of the semiconductor substrate relative to the gate and the source.

Optionally, the material for the first N-type epitaxial layer is epitaxial monocrystalline silicon having a thickness ranging between 5 μm and 20 μm, and a resistivity ranging between 30 Ω-cm and 60 Ω-cm.

Optionally, the material for the P-type barrier layer is epitaxial monocrystalline silicon having a resistivity ranging between 10 Ω-cm and 20 Ω-cm.

Optionally, the material for the second N-type epitaxial layer is epitaxial monocrystalline silicon having a thickness ranging between 3 μm and 5 μm, and a resistivity ranging between 30 Ω-cm and 60 Ω-cm.

Optionally, the process for forming the P-type barrier layer is a selective epitaxy process.

Optionally, the material of the hard mask layer could be chosen from silicon oxide, silicon nitride, and low temperature oxidation.

Optionally, the doping concentration and doping type of the second N-type epitaxial layer is the same as that of the first N-type epitaxial layer.

Correspondingly, the present disclosure provides a VDMOS device including a semiconductor substrate, and a first N-type epitaxial layer on the semiconductor substrate. The VDMOS device further includes a P-type barrier layer on both sides of the first N-type epitaxial layer and having a same thickness as that of the first N-type epitaxial layer; a second N-type epitaxial layer on the first N-type epitaxial layer and the P-type barrier layer; a gate on the second N-type epitaxial layer; a source in the second N-type epitaxial layer on both sides of the gate; and a drain on the back of the semiconductor substrate relative to the gate and the source.

Optionally, the material for the first N-type epitaxial layer is epitaxial monocrystalline silicon having a thickness ranging between 5 μm and 20 μm, and a resistivity ranging between 30 Ω-cm and 60 Ω-cm.

Optionally, the material for the P-type barrier layer is epitaxial monocrystalline silicon having a resistivity ranging between 10 Ω-cm and 20 Ω-cm.

Optionally, the material for the second N-type epitaxial layer is epitaxial monocrystalline silicon having a thickness ranging between 3 μm and 5 μm, and a resistivity ranging between 30 Ω-cm and 60 Ω-cm.

Comparing to the conventional technology, the present disclosure has many advantages, such as the following:

The P-type barrier layer on both sides of and adjacent to the N-type epitaxial layer is formed by etching the N-type epitaxial layer; the above-mentioned method forms the P-type barrier layer with good uniformity at one time without high energy ion implanting, multiple times of ion implantation and high temperature annealing; and the above-mentioned method is simple in process and easy to control, and decreases the fabrication cost of VDMOS devices.

### DESCRIPTION OF THE FIGURES

The above and other objects, characteristics and advantages of the present disclosure are clearer through reference to the attached figures. Among the figures, the same numerals refer to the same parts. It is not intended to draw the figures by zooming in or out of the actual size while focusing on illustrating the principle of the present invention.

FIGS. 1 through 4 are schematic cross-sectional views of a VDMOS device fabricated by a conventional method of fabricating VDMOS devices;

FIG. 5 is a flow chart of a method for fabricating VDMOS devices according to the present disclosure; and

FIGS. 6 through 12 are schematic-cross sectional views of a VDMOS device fabricated by the method for fabricating VDMOS devices of the present disclosure.

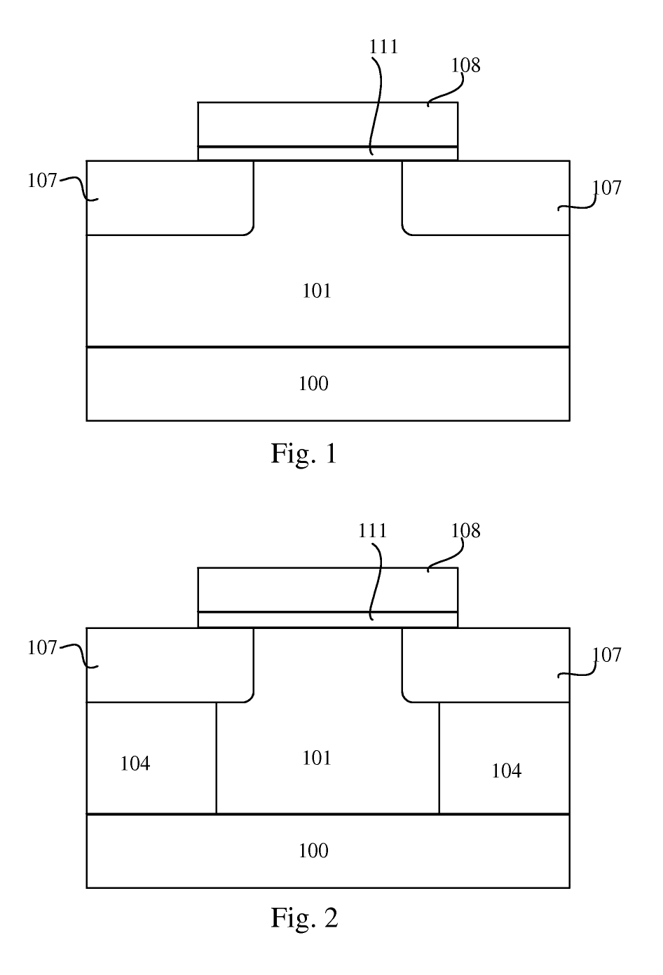

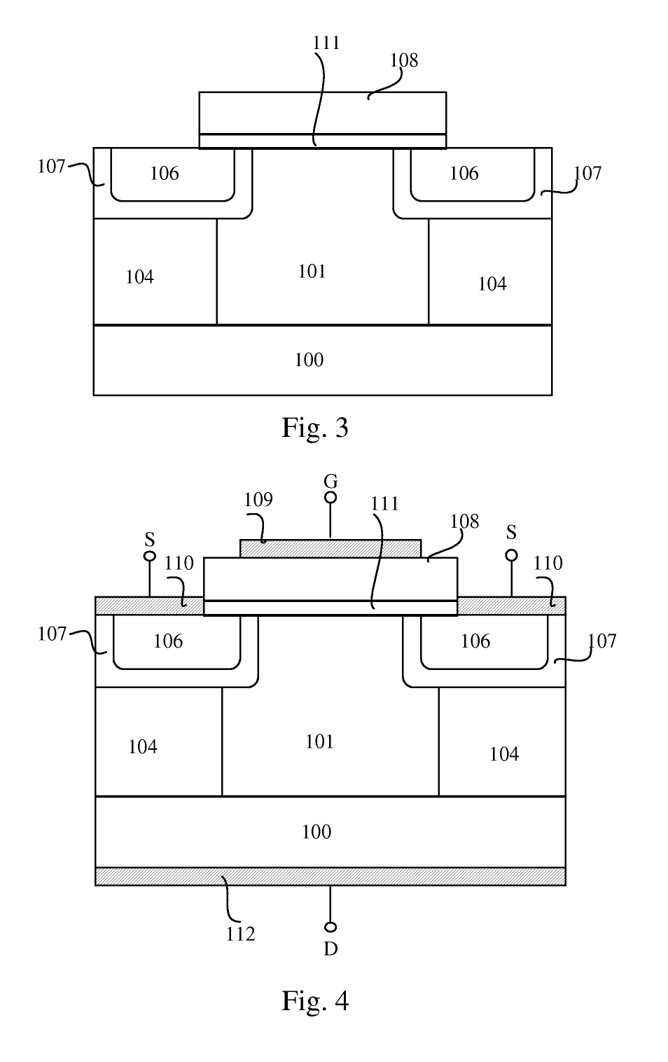

### DETAILED DESCRIPTION

In order to make the above and other objects, characteristics and advantages of the present disclosure clearer and easier to understand, embodiments of the present disclosure are described hereinafter in combination with the figures.

The disclosure hereinafter provides multiple embodiments or examples for different structures of the present invention. For simplifying the disclosure thereof, components and settings of the particular embodiments will be described below. It should be clear that such descriptions are only examples, and are not intended to limit the present invention. Besides, numeral marks and letters could be repeated in different embodiments disclosed herein. Such repetition is for simplification and clear purpose, and shall not refer to the relationship of the embodiments and/or the settings. Moreover, as the present disclosure provides examples for various particular processes and material, those skilled in the art shall have understanding of the applicability of other processes and/or materials.

In the below description, the structure that a first component is located “on” a second component shall include, either that the first and the second components are directly contacted, or that other components are located between the first and the second components, therefore the first and the second components are not directly contacted.

In order to decrease the conduction voltage drop of the VDMOS devices and to improve the channel resistor, the conventional technology increases the doping concentrate of a first N-type epitaxial layer and forms P-type barrier layers on both sides of the first N-type epitaxial layer, and the thickness of the P-type barrier layers is the same as that of the first N-type epitaxial layer. According to the conventional technology, the first N-type epitaxial layer is formed by multiple epitaxy steps, wherein a sub-epitaxial layer is formed in each epitaxy step, and the thickness of the sub-epitaxial layer is a part of the thickness of the first N-type epitaxial layer. After a sub-epitaxial layer is formed, P-type ion implantation is carried on the sub-epitaxial layer through a particular inclination angle (such as 45 degrees) to form sub-barrier layers on both sides of the sub-epitaxial layer, until the first N-type epitaxial layer is composed by the sub-epitaxial layers, and the sub-barrier layers on both sides of the sub-epitaxial layers compose the P-type barrier layer. For ensuring activation of the implanted ion, the P-type ion implantation step is usually followed by high temperature annealing steps.

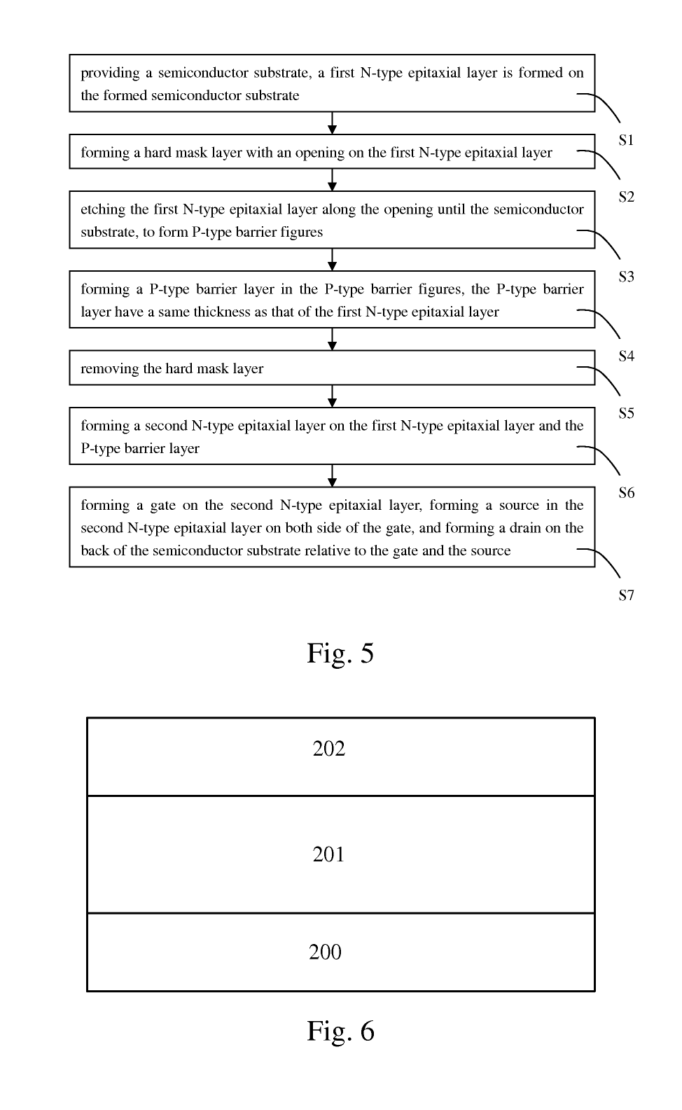

The conventional technology incorporates multiple ion implantation steps and high temperature annealing steps, such that the method for fabricating VDMOS devices is complex and is hard to control, and moreover the manufacturing cost of the VDMOS devices is higher. In contrast, according to the present disclosure, after the first N-type epitaxial layer is etched, a P-type barrier layer having a same thickness on both sides thereof is formed. A second N-type epitaxial layer is then formed on the first N-type epitaxial layer and the P-type barrier layer, and VDMOS devices are formed in the second N-type epitaxial layer. The method is simplified and easy to control, the VDMOS devices formed therefrom have stable characters, and the manufacturing cost is decreased. Referring to FIG. 5, which is a flow illustration of a method for fabricating VDMOS devices according to the present disclosure, the method includes:

Step S1, providing a semiconductor substrate, and forming a first N-type epitaxial layer on the semiconductor substrate;

Step S2, forming a hard mask layer having an opening on the first N-type epitaxial layer;

Step S3, etching the first N-type epitaxial layer along the opening until exposing the semiconductor substrate, to form P-type barrier figures;

Step S4, forming a P-type barrier layer having a same thickness as that of the first N-type epitaxial layer in the P-type barrier figures;

Step S5, removing the hard mask layer;

Step S6, forming a second N-type epitaxial layer on the first N-type epitaxial layer and the P-type barrier layer; and

Step S7, forming a gate electrode on the second N-type epitaxial layer, a source electrode in a portion of the second N-type epitaxial layer disposed on opposite sides of the gate, and a drain electrode on the back of the semiconductor substrate relative to the gate and the source.

The technology of the present disclosure is described in detail by incorporating the embodiment below. Referring to FIGS. 6 to 12, FIGS. 6 to 12 are sectional structures according to the method for fabricating VDMOS devices of the present disclosure.

Firstly, referring to FIG. 6, a semiconductor substrate 200 is provided. As an embodiment, the conductivity type of the semiconductor substrate 200 is N-type. A first N-type epitaxial layer 201 is formed on the semiconductor substrate 200. In at least one embodiment, the material for the first N-type epitaxial layer 201 is epitaxial monocrystalline silicon having a resistivity ranging from 30 Ω-cm to 60 Ω-cm, and a thickness ranging from 5 μm to 20 μm. The doped impurity is arsenic, with a doping concentration ranging from 1E13 cm⁻² to 1E15 cm⁻².

Referring to FIG. 6, depositing a hard mask layer 202 on the first N-type epitaxial layer 201, the material of the hard mask layer 202 could be chosen from silicon oxide or silicon nitride. As an embodiment of the present disclosure, the material of the hard mask layer 202 is chosen from silicon oxide, the range of its thickness is between 300 Å and 500 Å, and the method for forming it could be thermal oxidation or low temperature oxidation. As another embodiment, the material of the hard mask layer 202 is chosen from silicon nitride, the range of its thickness is between 500 Å and 3500 Å, and the method for forming it could be low pressure vapor deposition. As the hard mask layer 202 is silicon nitride, there is a buffer oxide layer with a thickness of 20 Å to 100 Å between the hard mask layer 202 and the first N-type epitaxial layer 201, for buffering the stress between the hard mask layer 202 and the first N-type epitaxial layer 201.

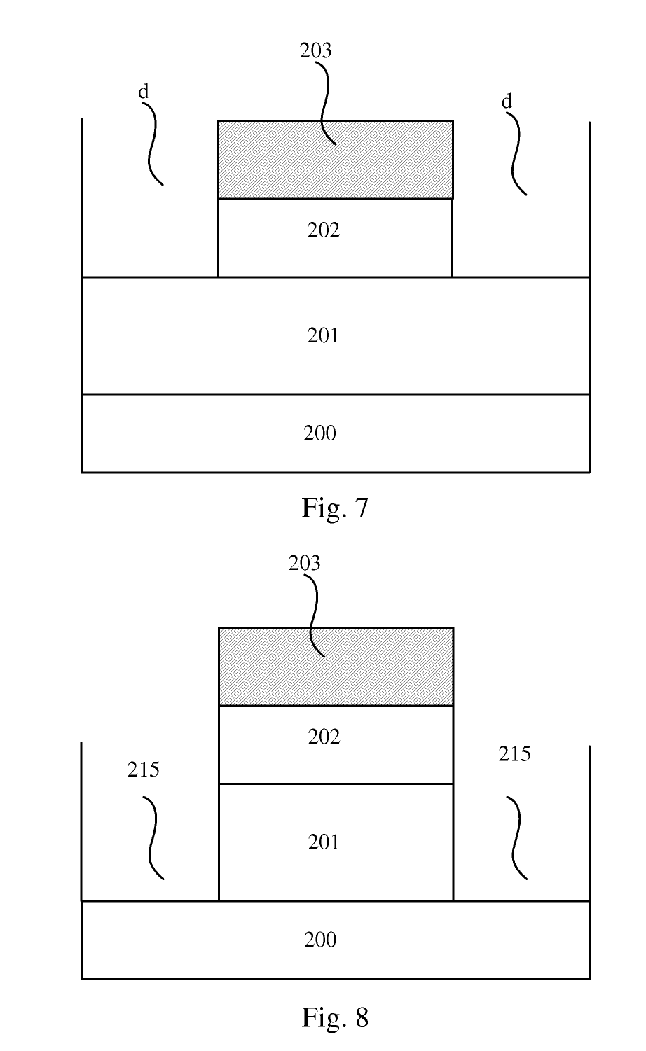

Referring to FIG. 7, a photoresist pattern 203 is formed on the hard mask layer 202. The photoresist pattern 203 covers part of the hard mask layer 202. Using the photoresist pattern 203 as the mask, a dry etch process is performed for removing the part of the hard mask layer 202 that is not covered by the photoresist pattern 203, so as to form an opening d in the hard mask layer 202. It shall be presented that, as an illustration, only the part of the hard mask layer 202 between two openings d is illustrated.

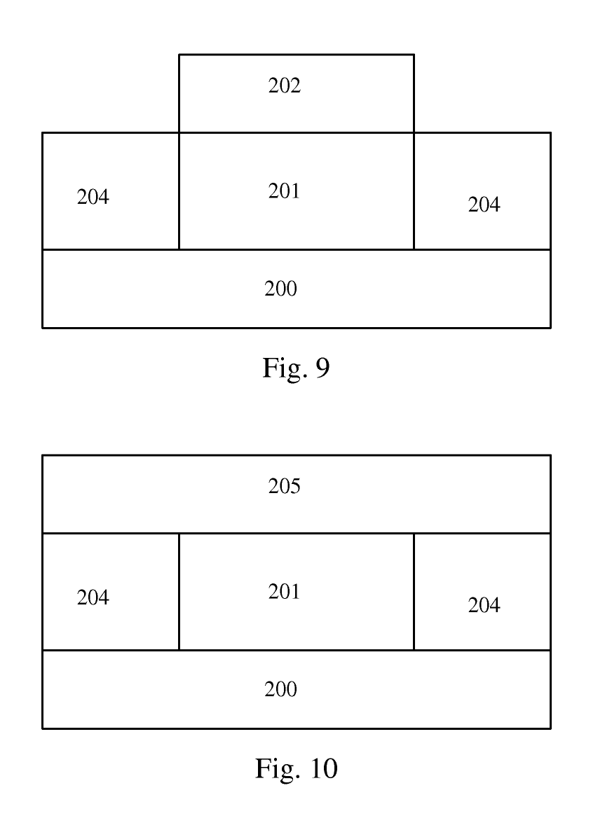

As a preferred embodiment, referring to FIG. 8, after the opening d in the hard mask layer 202 is formed, the photoresist pattern 203 is kept. By utilizing the same machine for etching the hard mask layer 202 to etch along the opening d until the semiconductor substrate 200 is exposed, therefore forming a P-type barrier FIG. 215, the time that the product is exposed to the air is thus reduced and particle pollution is thus reduced. Referring to FIG. 9, a wet etch process is used to remove the photoresist pattern 203. Subsequently, a P-type barrier layer 204 is formed in the P-type barrier FIG. 215, which has the same thickness as that of the first N-type epitaxial layer 201. The process for forming the P-type barrier layer 204 is a selective epitaxy process. The material for the P-type barrier layer 204 is the epitaxial monocrystalline silicon, the resistivity of which is 10 Ω-cm to 20 Ω-cm.

As another embodiment, a wet etch process may be used after the opening is formed in the hard mask layer to remove the photoresist pattern. Subsequently, a dry etch process may be used along the opening until the semiconductor substrate is exposed, to form a P-type barrier figure. The P-type barrier layer is formed in the P-type barrier figure, the material for the P-type barrier layer is the epitaxial poly silicon, and the resistivity of which is 10 Ω-cm to 20 Ω-cm.

Referring to FIG. 10, an etch process is used to remove the hard mask layer 202, and therefore the remaining first N-type epitaxial layer 201 is exposed. A second N-type epitaxial layer 205 is then formed on the first N-type epitaxial layer 201 and the P-type barrier layer 204. The material for the second N-type epitaxial layer 205 is the epitaxial monocrystalline silicon, the range for its thickness is between 3 μm and 5 μm, and the range for its resistivity is between 30 Ω-cm and 60 Ω-cm. The second N-type epitaxial layer 205 is formed with the same epitaxial deposition parameters as the first N-type epitaxial layer 201. Therefore, the resistivity, the doping concentration, and the doping type of the second N-type epitaxial layer 205 could be the same as that of the first N-type epitaxial layer 201.

Referring to FIG. 10, through the above steps, the P-type barrier layer 204 is formed on both sides of the first N-type epitaxial layer 201, while having an opposite conduction type thereto and having a same thickness as that of the first N-type epitaxial layer 201. Settings for the resistivity of the P-type barrier layer 204 shall be adjusted according to the doping concentration and resistivity of the P-type barrier in the conventional technology. The P-type barrier layer is formed by only one process step, and compared to the multiple step epitaxial process, multiple ion implantation, and high temperature annealing process in the conventional technology, the process steps are reduced, and the process complexity is lowered, therefore the manufacturing cost for the VDMOS devices is reduced.

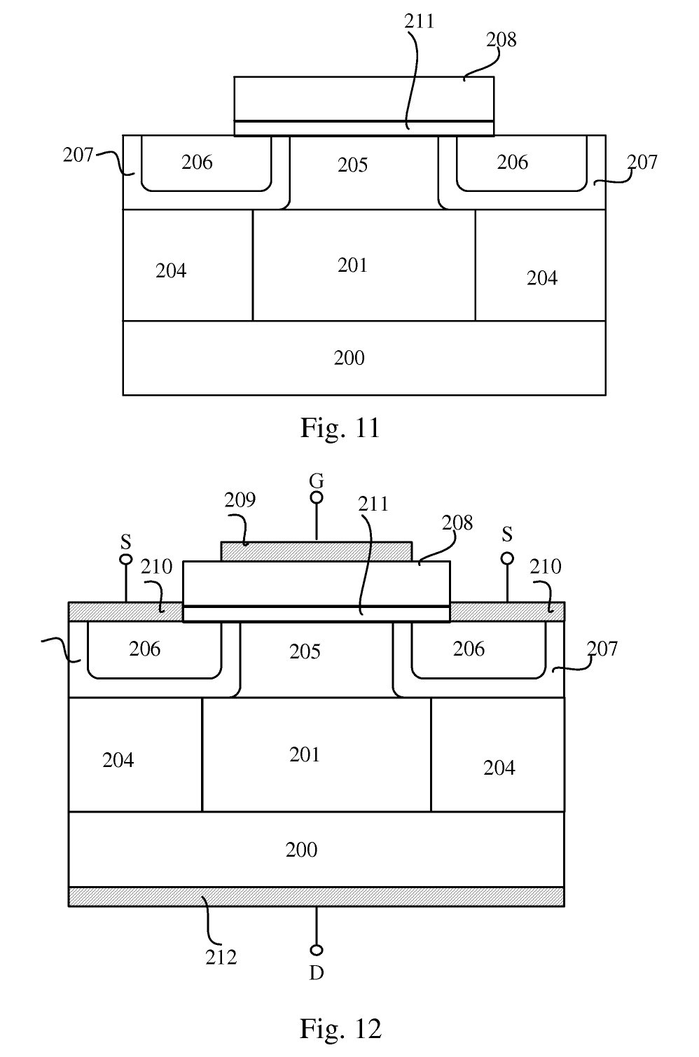

Referring to FIG. 11, an oxidation layer is deposited on the second N-type epitaxial layer 205. The oxidation layer is etched to form a gate dielectric layer 211. The width of the gate dielectric layer 211 is larger than that of the second N-type epitaxial layer 205 which is below the gate dielectric layer 211. The range for the thickness of the gate dielectric layer 211 is between 30 Å and 1000 Å. Poly silicon is formed on the gate dielectric layer 211, and the poly silicon is etched to form a poly silicon gate layer 208. The range for the thickness of the poly silicon gate layer is between 1000 Å and 4000 Å.

Further referring to FIG. 11, a P-well 207 is formed through P-well implantation in the second N-type epitaxial layer 205 located on both sides of the gate dielectric layer 211 and the poly silicon gate layer 208. The P-well 207 is contacted with the P-type barrier layer 204 and the first N-type epitaxial layer 205, and the width of the P-well 207 is larger than that of the P-type barrier layer 204 below the P-well 207. As an exemplary embodiment, the implanted elements for the P-well are boron and boron trifluoride, the range for its implantation energy is between 40 keV and 80 keV, and the range for the dose is between 1E12 cm⁻² and 1E13 cm⁻². Subsequently, an N-type heavy doped area 206 is formed by carrying an N-type heavy doped ion implantation in the P-well 207. The implanted elements for the N-type heavy doped ion implantation are phosphorus and arsenic, the range for its implantation energy is between 50 keV and 130 keV, and the range for the dose is between 1E15 cm⁻² and 2E16 cm⁻².

Further, referring to FIG. 12, a metallization process is carried out on the devices to form a source metal layer 210 on the N-type heavy doped area 206, and a gate metal layer 209 on the poly silicon gate layer 208. A back thinning process and a back metallization process is further carried out on the semiconductor substrate 200, for forming a drain metal layer 212 on the back of the semiconductor substrate 200 relative to the poly silicon gate layer 208 and the N-type heavy doped area 206. The “back” shall mean the side of the semiconductor substrate 200 opposite the side on which the devices are formed. The poly silicon gate layer 208 and the gate metal layer 209 cooperatively make a gate electrode G of the VDMOS device; the N-type heavy doped area 206 and the source metal layer 210 cooperatively make a source electrode S of the VDMOS device; and the semiconductor substrate 200 and the drain metal layer 212 cooperatively make a drain electrode D of the VDMOS.

Correspondingly, the present disclosure provides a VDMOS device, which, referring to FIG. 12, includes: an N-type semiconductor substrate 200; a first N-type epitaxial layer 201 on the semiconductor substrate 200; a P-type barrier layer 204 on both sides of the first N-type epitaxial layer 201 and having a same thickness thereof; a second N-type epitaxial layer 205 on the first N-type epitaxial layer 201 and the P-type epitaxial layer 204; a source electrode S of the VDMOS on the second N-type epitaxial layer 205; a gate electrode G in the second N-type epitaxial layer 205 on both sides of the source electrode S; and a drain electrode D of the VDMOS on the back of the semiconductor substrate 200 under the gate electrode G and the source electrode S. The “back” shall mean the side of the semiconductor substrate 200 opposite the side on which the devices are formed. The P-well 207, the N-type heavy doped area 206 in the P-well 207, and the source metal layer 210 on the N-type heavy doped area 206 cooperatively make the source electrode S. The poly silicon gate layer 208 on the second N-type epitaxial layer 205 and the gate metal layer 209 on the poly silicon gate layer 208 cooperatively make the gate electrode G. The semiconductor substrate 200 and the drain metal layer 212 on the back of the semiconductor substrate 200 cooperatively make the drain electrode D. The P-well 207 contacts with the first N-type epitaxial layer 201 and the P-type barrier layer 204, and the width of the P-well 207 is larger than that of the P-type barrier layer 204. In the present embodiment, the material for the first N-type epitaxial layer 201 is epitaxial monocrystalline silicon, having a thickness ranging between 5 μm and 20 μm, and a resistivity ranging between 30 Ω-cm and 60 Ω-cm. The material for the P-type barrier layer 204 is the epitaxial monocrystalline silicon, the resistivity of which is between 10 Ω-cm and 20 Ω-cm. The material for the second N-type epitaxial layer 205 is the epitaxial monocrystalline silicon, the range for its thickness is between 3 μm and 5 μm, and the range for its resistivity is between 30 Ω-cm and 60 Ω-cm.

The method for manufacturing VDMOS devices according to the present disclosure can also be used for fabricating an insulated gate bipolar transistor. As an embodiment, the method includes providing a semiconductor substrate, the substrate having a first N-type epitaxial layer formed thereon; forming a hard mask layer having an opening on the first N-type epitaxial layer; etching the first N-type epitaxial layer along the opening until the semiconductor substrate is exposed, to form P-type barrier figures; forming a P-type barrier layer in the P-type barrier figures, the P-type barrier layer having a same thickness as that of the first N-type epitaxial layer; removing the hard mask layer; forming a second N-type epitaxial layer on the first N-type epitaxial layer and the P-type barrier layer; forming a gate on the second N-type epitaxial layer; forming a source in the second N-type epitaxial layer on both sides of the gate; and forming a drain on the back of the semiconductor substrate relative to the gate and the source. Before forming the source, a P-type heavy doped ion implantation is carried out on the back of the semiconductor substrate. The “back” shall mean the side of the semiconductor substrate opposite the side on which the devices are formed.

As presented above, the present disclosure provides a VDMOS device and a method for fabricating the same. The method could directly form a P-type barrier layer on both sides of the first N-type epitaxial layer, thus reducing steps for fabricating VDMOS devices, and thus reducing the cost for fabricating VDMOS devices. The method could also be used for fabricating insulated gate bipolar transistors.

Although the present invention has been described through various preferred embodiments above, they are not for limiting the present invention. Persons in the present technical field can make possible changes and modifications according to the method and technical content as above, while being not departing from the spirit and scope of the present invention. Therefore, any modification, equivalence and changes in accordance with the technical substance of the present invention, not departing from the technical solutions disclosed herein, are included in the scope of claims of the present invention.

What is claimed is:

1. A method for fabricating VDMOS devices, wherein the method comprises:
providing a semiconductor substrate comprising a first N-type epitaxial layer formed on the semiconductor substrate;
forming a hard mask layer with an opening on the first N-type epitaxial layer;
etching the first N-type epitaxial layer along the opening until the semiconductor substrate is exposed, to form P-type barrier figures;
forming a P-type barrier layer having a same thickness as that of the first N-type epitaxial layer in the P-type barrier figures;
removing the hard mask layer;
forming a second N-type epitaxial layer on the first N-type epitaxial layer and the P-type barrier layer; and
forming a gate electrode on the second N-type epitaxial layer, a source electrode in a portion of the second N-type epitaxial layer disposed on opposite sides of the gate electrode, and a drain electrode on the back of the semiconductor substrate relative to the gate electrode and the source electrode.

2. The method for fabricating VDMOS devices of claim 1, wherein the material for the first N-type epitaxial layer is epitaxial monocrystalline silicon having a thickness ranging between 5 μm and 20 μm, and a resistivity ranging between 30 Ω-cm and 60 Ω-cm.

3. The method for fabricating VDMOS devices of claim 1, wherein the material for the P-type barrier layer is epitaxial monocrystalline silicon having a resistivity ranging between 10 Ω-cm and 20 Ω-cm.

4. The method for fabricating VDMOS devices of claim 1, wherein the material for the second N-type epitaxial layer is epitaxial monocrystalline silicon having a thickness ranging between 3 μm and 5 μm, and a resistivity ranging between 30 Ω-cm and 60 Ω-cm.

5. The method for fabricating VDMOS devices of claim 1, wherein the process for forming the P-type barrier layer is a selective epitaxy process.

6. The method for fabricating VDMOS devices of claim 1, wherein the material of the hard mask layer is selected from the group of silicon oxide, silicon nitride and low temperature oxidation.

7. The method for fabricating VDMOS devices of claim 1, wherein doping concentration and doping type of the second N-type epitaxial layer is the same as that of the first N-type epitaxial layer.

8. A VDMOS device, wherein the VDMOS device comprises:
a semiconductor substrate; and
a first N-type epitaxial layer on the semiconductor substrate;
wherein the VDMOS device further comprises:
a P-type barrier layer disposed on both sides of the first N-type epitaxial layer and having a same thickness as that of the first N-type epitaxial layer;
a second N-type epitaxial layer disposed on the first N-type epitaxial layer and the P-type barrier layer;
a gate on the second N-type epitaxial layer;
a source in the second N-type epitaxial layer on both sides of the gate; and
a drain on the back of the semiconductor substrate relative to the gate and the source.

9. The VDMOS device of claim 8, wherein the material for the first N-type epitaxial layer is epitaxial monocrystalline silicon having a thickness ranging between 5 μm and 20 μm, and a resistivity ranging between 30 Ω-cm and 60 Ω-cm.

10. The VDMOS device of claim 8, wherein the material for the P-type barrier layer is epitaxial monocrystalline silicon having a resistivity ranging between 10 Ω-cm and 20 Ω-cm.

11. The VDMOS device of claim 8, wherein the material for the second N-type epitaxial layer is epitaxial monocrystalline silicon having a thickness ranging between 3 μm and 5 μm, and a resistivity ranging between 30 Ω-cm and 60 Ω-cm.
